(19) United States
(12) Patent Application Publication
(10) Pub. No.: US 2026/0043126 A1
(43) Pub. Date: Feb. 12, 2026

(54) DEPOSITION RING FOR PHYSICAL VAPOR DEPOSITION CHAMBER

(71) Applicant: Applied Materials, Inc., Santa Clara, CA (US)

(72) Inventors: Zheyuan Chen, Sunnyvale, CA (US); Avinash Nayak, Bengaluru (IN); Jianxin Lei, Saratoga, CA (US); Sundarapandian Ramalinga Vijayalakshmi Reddy, Bangalore (IN); Allyson N. Vu, San Jose, CA (US)

(73) Assignee: Applied Materials, Inc., Santa Clara, CA (US)

(21) Appl. No.: 18/799,554

(22) Filed: Aug. 9, 2024

(51) Int. Cl. C23C 14/50; C23C 14/06; C23C 14/34; H01L 21/285

(52) U.S. Cl. CPC C23C 14/50; C23C 14/0641; C23C 14/34; H01L 21/28568

(57) ABSTRACT

Physical vapor deposition (PVD) chambers and deposition rings for physical vapor deposition (PVD) chambers are described. The deposition ring comprises a ring-shaped body having an upper portion and a lower portion, each of the upper portion and the lower portion independently comprising an inner diameter surface and an outer diameter surface defining an upper portion thickness and a lower portion thickness, and a top surface and a bottom surface defining an upper portion height and a lower portion height, the upper portion height greater than the lower portion height; and a plurality of circumferentially spaced notches formed along an edge of the inner diameter surface of the lower portion, wherein at least a portion of the upper portion defines a convex shape.

### TECHNICAL FIELD

Embodiments of the disclosure pertain to the field of electronic device fabrication, and in particular, to integrated circuit fabrication. In particular, embodiments of the disclosure pertain to physical vapor deposition (PVD) chambers and deposition rings for physical vapor deposition (PVD) chambers.

### BACKGROUND

Sputtering, alternatively called physical vapor deposition (PVD), has long been used in depositing metals and related materials in the fabrication of semiconductor integrated circuits. Plasma sputtering may be accomplished using either direct current (DC) sputtering or radiofrequency (RF) sputtering. Plasma sputtering typically includes a magnetron positioned at the back of the sputtering target to project a magnetic field into the processing space to increase the density of the plasma and enhance the sputtering rate. Magnets used in the magnetron are typically closed loop for DC sputtering and open loop for RF sputtering.

During PVD of titanium nitride (TiN) on a substrate (e.g., a wafer), for example, there is threshold voltage (Vₜ) variation at the wafer center-edge due to a non-uniform ratio of titanium atoms to nitrogen atoms in the deposited titanium nitride (TiN) film. Threshold voltage (Vₜ) variation is correlated with a greater amount of nitrogen atoms in the ratio of titanium atoms to nitrogen atoms in the deposited titanium nitride (TiN) film. More specifically, a greater amount of nitrogen atoms in the ratio of titanium atoms to nitrogen atoms in the deposited titanium nitride (TiN) film corresponds to a higher threshold voltage (Vₜ). High-speed performance and low-power operation can be achieved by utilizing low-threshold voltage (Vₜ) transistors. Therefore, high threshold voltage (Vₜ) and threshold voltage (Vₜ) variation may be detrimental to electronic device performance.

It is thought that the ratio of titanium atoms to nitrogen atoms (i.e., titanium/nitrogen ratio) in the deposited titanium nitride (TiN) film may be correlated to the amount of space provided between the target and the semiconductor substrate (e.g., wafer) on which the titanium nitride (TiN) film is deposited. It has been found that current deposition rings do not provide a sufficient amount of space to meet manufacturing requirements, as exhibited by the threshold voltage (Vₜ) variation at the wafer center-edge due to the non-uniform ratio of titanium atoms to nitrogen atoms in the deposited titanium nitride (TiN) film.

Therefore, there is a need in the art for improved deposition rings that provide improved titanium/nitrogen ratio uniformity.

### SUMMARY

One or more embodiments of the disclosure are directed to a deposition ring comprising: a ring-shaped body having an upper portion and a lower portion, each of the upper portion and the lower portion independently comprising an inner diameter surface and an outer diameter surface defining an upper portion thickness and a lower portion thickness, and a top surface and a bottom surface defining an upper portion height and a lower portion height, the upper portion height greater than the lower portion height; and a plurality of circumferentially spaced notches formed along an edge of the inner diameter surface of the lower portion, wherein at least a portion of the upper portion defines a convex shape.

Additional embodiments are directed to a processing chamber comprising: a target backing plate in a top portion of the processing chamber; a substrate support in a bottom portion of the processing chamber, the substrate support having a support surface spaced a distance from the target backing plate to form a process cavity; a deposition ring positioned at an outer periphery of the substrate support; and a shield forming an outer bound of the process cavity, wherein the shield has a top shield end in the top portion of the processing chamber and a bottom shield end in the bottom portion of the processing chamber, the top end positioned around a periphery of the target backing plate and the bottom end positioned around a periphery of the substrate support, the bottom end including a contoured surface having a complementary shape to the outer portion of the deposition ring.

Further embodiments are directed to a processing method comprising exposing a semiconductor substrate in a physical vapor deposition (PVD) processing chamber to a target comprising a titanium-containing material to deposit a titanium nitride (TiN) film directly on the semiconductor substrate. The physical vapor deposition (PVD) processing chamber comprises the deposition ring described herein.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the Figures, in which like references indicate similar elements.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label, unless specifically indicated otherwise.

FIG. 1 illustrates an isometric schematic view of a deposition ring in accordance with one or more embodiments of the disclosure;

FIG. 2A illustrates a top schematic view of the deposition ring of FIG. 1;

FIG. 2B illustrates a bottom schematic view of the deposition ring of FIG. 1;

FIG. 3A illustrates a cross-sectional schematic view of the deposition ring of FIG. 1 positioned on a substrate support;

FIG. 3B illustrates an enlarged cross-sectional schematic view of a portion of the deposition ring of FIG. 1 positioned on a substrate support;

FIG. 3C illustrates an enlarged cross-sectional schematic view of a portion of the deposition ring of FIG. 1 positioned on a substrate support; and

FIG. 4 illustrates a cross-sectional schematic view of a portion of a physical vapor deposition (PVD) chamber including the deposition ring of FIG. 1 positioned on a substrate support.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of about.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “some embodiments,” “certain embodiments,” “one or more embodiment” or “an embodiment” means that a particular feature, structure, material, or characteristic described in connection with the embodiment is included in at least one embodiment of the disclosure. Thus, the appearances of the phrases such as “in some embodiments,” “in one or more embodiment,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” may include materials such as silicon (including doped or undoped silicon), silicon oxide, strained silicon, silicon on insulator (SOI), carbon doped silicon oxides, amorphous silicon, germanium, silicon germanium (SiGe), gallium arsenide, glass, sapphire, and any other materials such as metals, metal nitrides, metal alloys, and other conductive materials, depending on the application. Substrates include, without limitation, semiconductor substrates. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The substrate may have one or more features formed therein, one or more layers formed thereon, or combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls comprising, for example, a dielectric material, and a bottom extending into the substrate, the bottom comprising, for example, a metallic material, or vias which have one or more sidewall extending into the substrate to a bottom, and slot vias.

The features described herein can extend vertically into the substrate and/or laterally within the substrate. Unless specifically indicated otherwise, the features described herein are not limited to either of a vertically extending feature or a laterally extending feature. In one or more embodiments, the substrate comprises at least one vertically extending feature. In one or more embodiments, the substrate comprises at least one laterally extending feature. In one or more embodiments, the substrate comprises at least one vertically extending feature and at least one laterally extending feature.

The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, 40:1, 50:1, 60:1, 70:1, 80:1, 90:1, 100:1, 125:1, or 150:1. In one or more embodiments, the aspect ratio of the features described herein is in a range of from 1:1 to 150:1.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used in this specification and the appended claims, the terms “precursor”, “reactant”, “reactive gas” and the like are used interchangeably to refer to any gaseous species that can react with the substrate surface.

Sputtering, alternatively called physical vapor deposition (PVD), has long been used in depositing metals and related materials in the fabrication of semiconductor integrated circuits. Plasma sputtering may be accomplished using either direct current (DC) sputtering or radiofrequency (RF) sputtering. Plasma sputtering typically includes a magnetron positioned at the back of the sputtering target to project a magnetic field into the processing space to increase the density of the plasma and enhance the sputtering rate. Magnets used in the magnetron are typically closed loop for DC sputtering and open loop for RF sputtering.

“Physical vapor deposition (PVD),” as described herein, refers to a process technology in which atoms of conducting material, such as titanium nitride (TiN), for example, are sputtered from a target of pure material, then deposited on a substrate to create the conducting circuitry within an integrated circuit. “Sputtering,” as used herein, refers to a method of depositing a film where atoms are ejected from a solid target material due to bombardment of the target by energetic particles. The “target” in PVD as described herein, is the source of the material to be deposited. Atoms are ejected from the target as a result of the bombardment of energetic particles.

Generally, front-end of line (FEOL) refers to the first portion of integrated circuit fabrication, including transistor fabrication, middle of line (MOL) connects the transistor and interconnect parts of a chip using a series of contact structures, and back-end of line (BEOL) refers to a series of process steps after transistor fabrication through completion of a semiconductor wafer.

During PVD of titanium nitride (TiN) on a substrate (e.g., a wafer), for example, there is threshold voltage (Vₜ) variation at the wafer center-edge due to a non-uniform ratio of titanium atoms to nitrogen atoms in the deposited titanium nitride (TiN) film.

Threshold voltage (Vₜ) variation is correlated with a greater amount of nitrogen atoms in the ratio of titanium atoms to nitrogen atoms in the deposited titanium nitride (TiN) film. More specifically, a greater amount of nitrogen atoms in the ratio of titanium atoms to nitrogen atoms in the deposited titanium nitride (TiN) film corresponds to a higher threshold voltage (Vₜ). High-speed performance and low-power operation can be achieved by utilizing low-threshold voltage (Vₜ) transistors. Therefore, high threshold voltage (Vₜ) and threshold voltage (Vₜ) variation may be detrimental to electronic device performance.

It is thought that the ratio of titanium atoms to nitrogen atoms (i.e., titanium/nitrogen ratio) in the deposited titanium nitride (TiN) film may be correlated to the amount of space provided between the target and the semiconductor substrate (e.g., wafer) on which the titanium nitride (TiN) film is deposited.

The amount of space provided between the target and the semiconductor substrate (e.g., wafer) is referred to herein as “target-to-wafer spacing.” It has been found that current deposition rings do not provide sufficient target-to-wafer spacing to meet manufacturing requirements, as exhibited by the threshold voltage (Vₜ) variation at the wafer center-edge due to the non-uniform ratio of titanium atoms to nitrogen atoms in the deposited titanium nitride (TiN) film.

Embodiments of the present disclosure advantageously provide improved deposition rings that can be used in FEOL, MOL, and/or BEOL processes. The deposition rings of one or embodiments can advantageously be used in, without limitation, logic and memory device fabrication processes.

Some embodiments are directed to a deposition ring for a physical vapor deposition (PVD) processing chamber for deposition of titanium nitride (TiN). Some embodiments advantageously provide deposition rings that provide improved titanium/nitrogen ratio uniformity in the deposition of titanium nitride (TiN).

The titanium nitride (TiN) films can be used in, without limitation, logic and memory applications. In one or more embodiments, the titanium nitride (TiN) film is used as a barrier material for at least tungsten, ruthenium, and cobalt in, for example, interconnect structures. Additionally, in one or more embodiments, the titanium nitride (TiN) film can be used as the high-κ cap and as a p-metal material in gate stacks/metal gates.

In one or more embodiments, the titanium nitride (TiN) film is used in a dynamic random-access memory (DRAM) device. As used herein, the term “dynamic random-access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor.

Advantageously, the deposition ring according to one or more embodiments provides longer target-to-wafer spacing compared to current deposition rings. With current deposition rings, the maximum target-to-wafer spacing is in a range of from 170 mm to 174 mm. Advantageously, with the deposition ring described herein, the maximum target-to-wafer spacing is in a range of from 184 mm to 188 mm. Advantageously, the deposition ring described herein provides sufficient target-to-wafer spacing to meet manufacturing requirements.

As a result of the longer target-to-wafer spacing, there is, advantageously, an improvement in the uniformity of a ratio of titanium atoms to nitrogen atoms (i.e., titanium/nitrogen ratio) in the deposited titanium nitride (TiN) film. In particular, it has been found that during use of current deposition rings, there is threshold voltage (Vₜ) variation at wafer center-edge due to a non-uniform ratio of titanium atoms to nitrogen atoms in the deposited titanium nitride (TiN) film.

Additionally, the deposition rings described herein advantageously provide lower threshold voltage (Vₜ) compared to current deposition rings in titanium nitride (TiN) deposition.

Advantageously, the deposition rings described herein are reusable and can be used in a plurality of deposition process cycles. For example, the deposition rings described herein can advantageously be used in a plurality of titanium nitride (TiN) deposition process cycles. Accordingly, the deposition rings described herein can advantageously increase the lifetime of other components in the processing chamber such as, for example, a process kit, as would be understood and appreciated by a skilled artisan.

The embodiments of the disclosure are described by way of the Figures, which illustrate a deposition ring 100 and a portion of a physical vapor deposition (PVD) chamber 200 including the deposition ring 100, in accordance with one or more embodiments of the disclosure.

In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

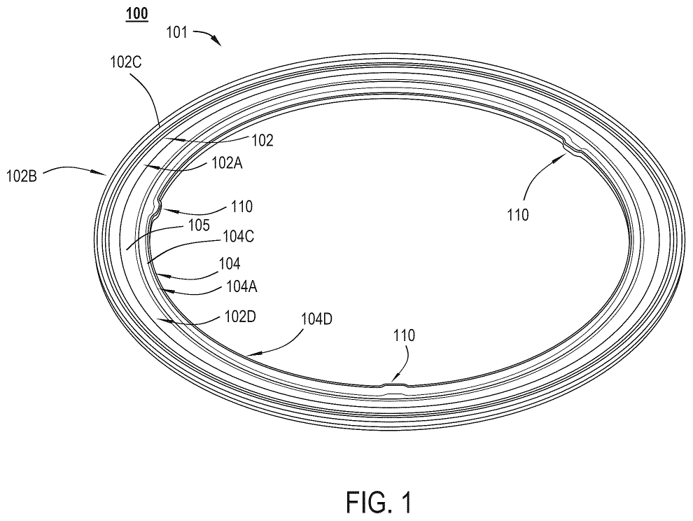

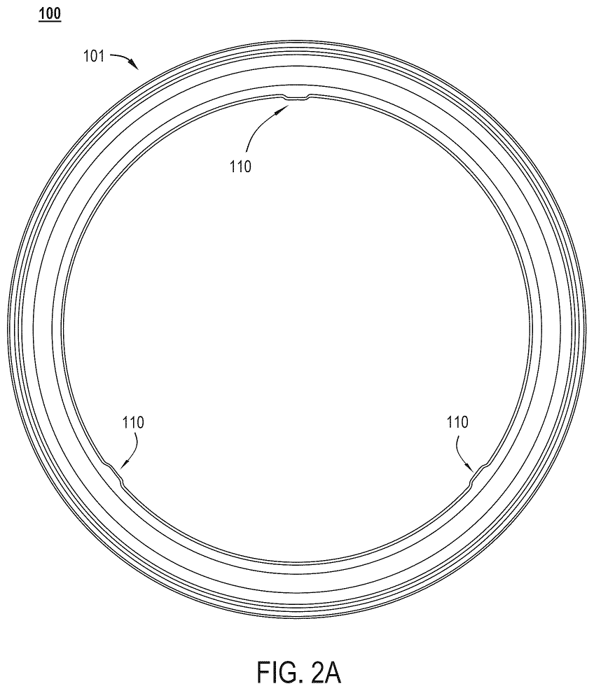

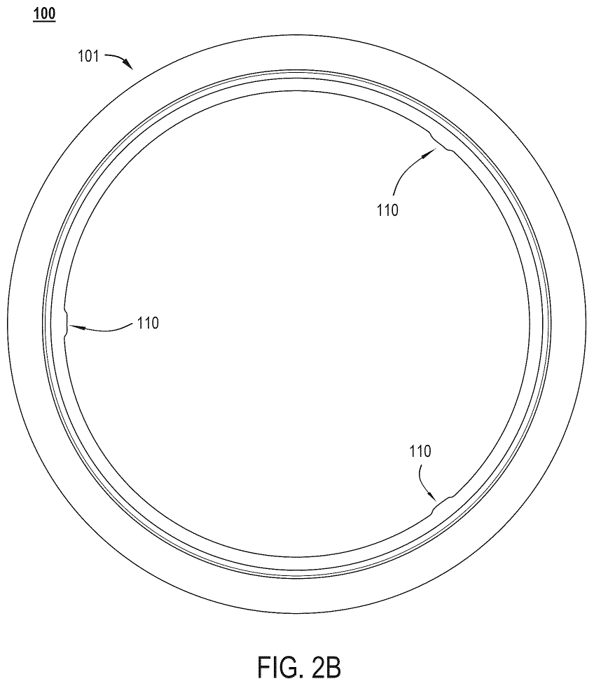

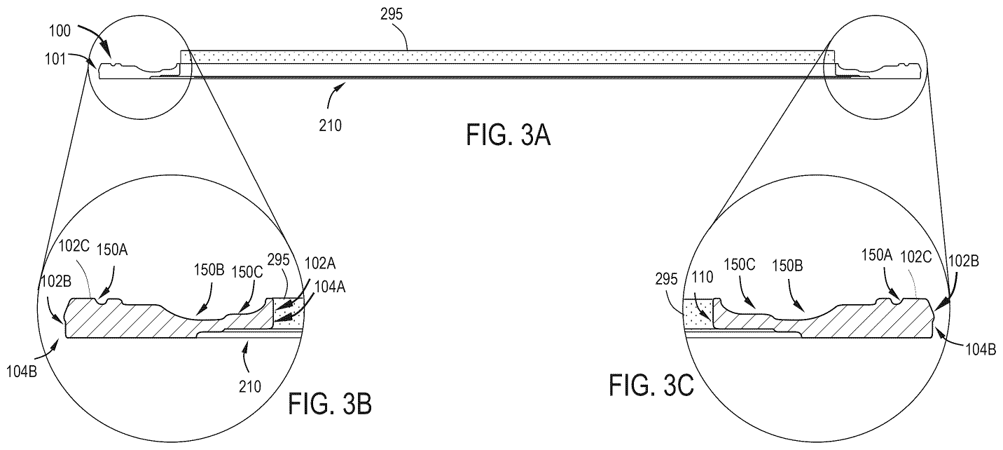

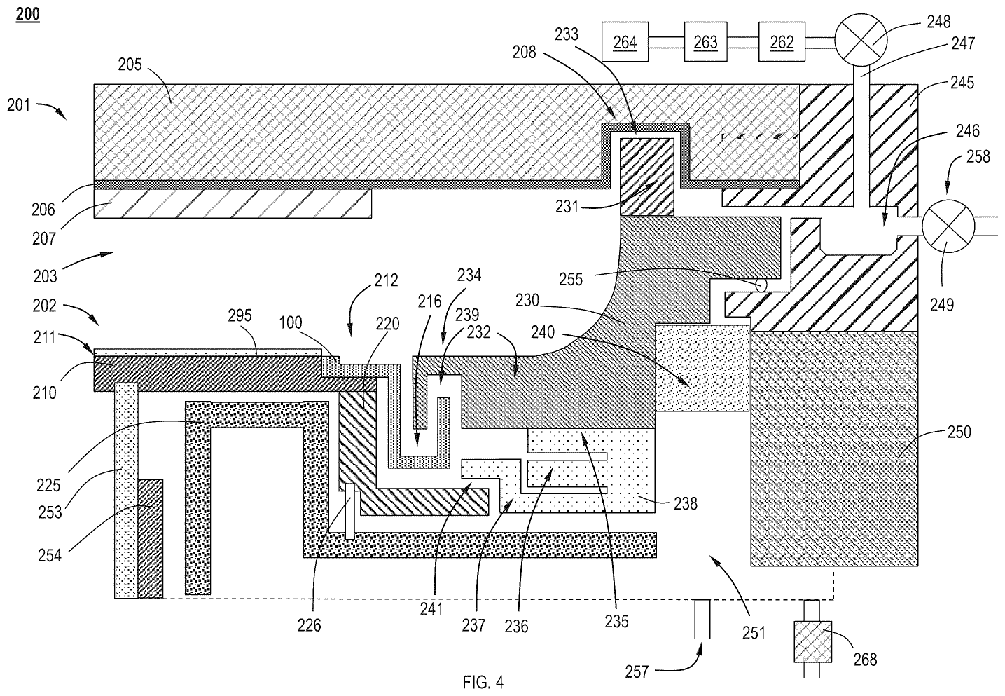

FIG. 1 illustrates an isometric schematic view of the deposition ring 100. FIG. 2A illustrates a top schematic view of the deposition ring 100 of FIG. 1. FIG. 2B illustrates a bottom schematic view of the deposition ring 100 of FIG. 1. FIG. 3A illustrates a cross-sectional schematic view of the deposition ring 100 of FIG. 1 positioned on a substrate support 210. FIGS. 3B and 3C illustrate enlarged cross-sectional schematic views of a portion of the deposition ring 100 of FIG. 1 positioned on the substrate support 210. FIG. 4 illustrates a cross-sectional schematic view of a portion of the processing chamber 200, e.g., a physical vapor deposition (PVD) chamber, including the deposition ring 100 of FIG. 1 positioned on the substrate support 210.

Referring to FIGS. 1, 2A-2B, and 3A-3C, the deposition ring 100 comprises a ring-shaped body 101 having an upper portion 102 and a lower portion 104. Each of the upper portion 102 and the lower portion 104 independently comprise an inner diameter surface and an outer diameter surface defining an upper portion thickness and a lower portion thickness.

The upper portion 102 includes an inner diameter surface 102A and an outer diameter surface 102B defining the upper portion thickness. The lower portion 104 includes an inner diameter surface 104A and an outer diameter surface 104B defining the lower portion thickness.

The upper portion thickness can be any suitable thickness. The lower portion thickness can be any suitable thickness. Each of the upper portion and the lower portion may independently have a thickness of about 0.269 inches ±0.10 inches.

In one or more embodiments, the upper portion 102 and the lower portion 104 are separated by an annular ring 105. In one or more embodiments, the annular ring is entirely contained within the ring-shaped body 101.

Each of the upper portion 102 and the lower portion 104 respectively comprises a top surface and a bottom surface defining an upper portion height and a lower portion height. The upper portion 102 comprises a top surface 102C and a bottom surface 102D. In one or more embodiments, the bottom surface 102D of the upper portion 102 is a top surface of the annular ring 105.

The lower portion 104 comprises a top surface 104C and a bottom surface 104D. In one or more embodiments, the top surface 104C of the lower portion 104 is a bottom surface of the annular ring 105.

In one or more embodiments, a sum of the upper portion height and the lower portion height is in a range of from 0.2 inches to 0.3 inches. In one or more embodiments, the upper portion height is greater than the lower portion height. In one or more embodiments, the upper portion height and the lower portion height are the same.

The ring-shaped body 101 has an inner diameter in a range of from 10 inches to 12 inches. In one or more embodiments, the inner diameter of the upper portion 102 is greater than the inner diameter of the lower portion 104. In one or more embodiments, the inner diameter of the upper portion 102 and the inner diameter of the lower portion 104 are each independently in the range of from 10 inches to 12 inches.

The ring-shaped body 101 has an outer diameter in a range of from 13 inches to 15 inches. In one or more embodiments, the outer diameter of the upper portion 102 is greater than the outer diameter of the lower portion 104. In one or more embodiments, the outer diameter of the upper portion 102 and the outer diameter of the lower portion 104 is each independently in the range of from 13 inches to 15 inches.

The deposition ring 100 comprises a plurality of circumferentially spaced notches 110 formed along an edge of the inner diameter surface 104A of the lower portion 104.

The plurality of circumferentially spaced notches 110 can include any suitable number of circumferentially spaced notches greater than 1. In one or more embodiments, the plurality of circumferentially spaced notches 110 includes three notches. In one or more embodiments, the plurality of circumferentially spaced notches 110 includes four notches, five notches, six notches, eight notches, nine notches, or ten notches.

In one or more embodiments, at least one of the plurality of circumferentially spaced notches 110 is tapered inwardly. In one or more embodiments, each of the plurality of circumferentially spaced notches 110 is tapered inwardly.

FIG. 3A illustrates a cross-sectional schematic view of the deposition ring 100 of FIG. 1 positioned on a substrate support 210. FIGS. 3B and 3C illustrate enlarged cross-sectional schematic views of a portion of the deposition ring 100 of FIG. 1 positioned on the substrate support 210. In one or more embodiments, the deposition ring 100 defines a shape that is complementary to the substrate support 210 such that the deposition ring 100 sits on the substrate support 210, and the deposition ring 100 and the substrate support 210 are in fluid communication. The deposition ring 100 is removable from the substrate support 210.

In FIG. 3A-3C, the inner diameter surface 102A, the inner diameter surface 104A, the outer diameter surface 102B, the outer diameter surface 104B, the top surface 102C of the upper portion 102, one of the plurality of circumferentially spaced notches 110, and a plurality of indentations are illustrated. FIG. 3A-3C also illustrate a wafer (e.g., a substrate 295) positioned on the substrate support 210 for processing. The substrate 295 can include any substrate as described herein. The deposition ring 100 circumscribes the substrate 295 to protect the substrate support 210 during processing.

In one or more embodiments, at least a portion of the upper portion 102 of the deposition ring 100 defines a convex shape. In FIG. 3A-3C, the top surface 102C of the upper portion 102 includes a plurality of indentations. In some embodiments, one or more the plurality of indentations defines a convex shape. In some embodiments, each of the plurality of indentations define various differing convex shapes. In one or more embodiments, the plurality of indentations includes a first indentation 150A, a second indentation 150B, and a third indentation 150C. The plurality of indentations is not limited to the first indentation 150A, the second indentation 150B, and the third indentation 150C. The plurality of indentations can include any suitable number of indentations.

The first indentation 150A, the second indentation 150B, and the third indentation 150C are illustrated in FIGS. 3B and 3C. Advantageously, the first indentation 150A, the second indentation 150B, and the third indentation 150C, collectively, are configured to prevent unwanted deposition on other components in a physical vapor deposition (PVD) chamber. In specific embodiments, the first indentation 150A, the second indentation 150B, and the third indentation 150C, collectively, advantageously prevent unwanted deposition on other components in a physical vapor deposition (PVD) chamber during a titanium nitride (TiN) deposition process.

In one or more embodiments, the convex shape of the first indentation 150A is smaller in size than each of the second indentation 150B and the third indentation 150C. In one or more embodiments, the first indentation 150A is closer to the outer diameter surface 102B than the inner diameter surface 102A.

In specific embodiments, the second indentation 150B and the third indentation 150C, collectively, advantageously prevent unwanted deposition on other components in a physical vapor deposition (PVD) chamber during a titanium nitride (TiN) deposition process. The second indentation 150B and the third indentation 150C, collectively, define a contour that provides a suitable surface near the substrate on which the titanium nitride (TiN) film is deposited, to absorb titanium atoms and nitrogen atoms while advantageously, preventing unwanted deposition on other components in the physical vapor deposition (PVD) chamber during the titanium nitride (TiN) deposition process.

In one or more embodiments, the second indentation 150B, viewed from left to right, defines a curved shape that extends upwards towards the third indentation 150C. The third indentation 150C extends upwards towards the top surface 102C, towards the inner diameter surface 102A of the upper portion 102.

In some embodiments, one or more of the second indentation 150B and the third indentation 150C are closer to the inner diameter surface 102A than the outer diameter surface 102B. In some embodiments, each of the second indentation 150B and the third indentation 150C are closer to the inner diameter surface 102A than the outer diameter surface 102B.

In some embodiments, the convex shape of the second indentation 150B is larger in size than the convex shape of the third indentation 150C. In some embodiments, the convex shape of the second indentation 150B and the convex shape of the third indentation 150C have the same size.

The deposition ring 100 can be made by any suitable process. In one or more embodiments, the deposition ring 100 is a monolithic component.

The deposition ring 100 can be formed from any suitable material. In one or more embodiments, the deposition ring 100 comprises a dielectric material. In one or more embodiments, the deposition ring 100 comprises, consists essentially of, or consists of aluminum oxide (Al₂O₃).

Referring now to FIG. 4, the processing chamber 200, e.g., the physical vapor deposition (PVD) chamber, comprises a top portion 201, a bottom portion 202, and at least one process cavity 203 between the top portion 201 and the bottom portion 202. In one or more embodiments, the processing chamber 200 is an RF PVD processing chamber. In one or more embodiments, the processing chamber 200 is a DC PVD processing chamber.

The top portion 201 comprises a target backing plate 205 facing the at least one process cavity 203. The target backing plate 205 can include any suitable material. In some embodiments, the target backing plate 205 comprises copper chromium (CuCr). In some embodiments, the target backing plate 205 supports a target 207, and the target 207 faces the at least one process cavity 203.

The target 207 can comprise any suitable material. In one or more embodiments, the target 207 comprises a titanium-containing material. In one or more embodiments, the target 207 is configured to sputter the titanium-containing material in a physical vapor deposition (PVD) process.

In some embodiments, the top portion 201 further comprises a target bond 206. The target bond 206 attaches the target 207 to the target backing plate 205. The target bond 206 is located between the target backing plate 205 and the target 207. The target bond 206 can be any suitable bonding material known to the skilled artisan.

The bottom portion 202 comprises the substrate support 210 having a support surface 211 spaced a distance from the target 207 to form the process cavity 203. In one or more embodiments, a wafer (e.g., a substrate 295) is positioned on the support surface 211 for processing. As will be described further herein, the distance between the substrate 295 and the target 207 is referred to as “target-to-wafer spacing.”

In some embodiments, the substrate support 210 comprises a mounting plate supporting a pedestal and electrostatic chuck. The electrostatic chuck (ESC) is protected from the reactive gases in the process cavity 203 with an electrostatic chuck cover. In some embodiments, the electrostatic chuck (ESC) has a cover comprising a protective wafer. In some embodiments, when in cleaning mode, for example, the protective wafer functions to protect the electrostatic chuck (ESC) from damage due to the reactive species in the process cavity 203.

In some embodiments, the deposition ring 100 is positioned at an outer periphery 212 of the substrate support 210. The deposition ring 100 circumscribes the substrate 295 to protect the substrate support 210 during processing. As will be understood and appreciate by the skilled artisan, the processing chamber 200 can include other components such as a cover ring, for example, positioned in contact with or around the deposition ring 100.

Advantageously, the deposition ring 100 provides longer target-to-wafer spacing compared to current deposition rings. With current deposition rings, the maximum target-to-wafer spacing is in a range of from 170 mm to 174 mm. Advantageously, with the deposition ring 100, the maximum target-to-wafer spacing is in a range of from 184 mm to 188 mm.

The bottom portion 202 comprises a grounding bracket 225 below the substrate support 210, the deposition ring 100, and a shield 230. The grounding bracket 225 can comprise any suitable material. In some embodiments, the grounding bracket 225 comprises stainless steel. In some embodiments, the grounding bracket 225 comprises nickel plated stainless steel.

The shield 230 forms an outer bound of the process cavity 203. In some embodiments, the shield 230 comprises a shield top end 231 in the top portion 201 and a shield bottom end 232 in the bottom portion 202. In some embodiments, the shield 230 is a single component. In some embodiments, the shield top end 231 and the shield bottom end 232 are separate components and are fastened together by fasteners.

The shield top end 231 comprises a complementary shape to a groove 208 of the target backing plate 205. The top portion 201 of the processing chamber 200 comprises a top gas flow path 233 between the groove 208 at the periphery of the target backing plate 205 and the shield top end 231. In some embodiments, as illustrated, the target bond 206 extends along the contours of the groove 208 of the target backing plate 205.

The shield bottom end 232 is positioned around the outer periphery 212 of the substrate support 210. The shield bottom end 232 includes a contoured surface 234 having a complementary shape to the outer diameter surface 102B of the deposition ring 100. The shield bottom end 232 and the deposition ring 100 forms a bottom gas flow path 239. Stated differently, the bottom gas flow path 239 extends between the contoured surface 234 of the shield bottom end 232 and the outer diameter surface102B of the deposition ring 100.

In some embodiments, the bottom portion 202 of the processing chamber 200 comprises a bottom gas flow path 239 between the shield bottom end 232 and the deposition ring 100.

In one or more embodiments, the processing chamber 200 comprises a heater 240. In some embodiments, the heater 240 acts as a large thermal mass to maintain a desired temperature within the process cavity 203. The heater 240 is located on an outer periphery of the shield bottom end 232. The heater 240 functions to increase heat mass capacity of the processing chamber 200. In some embodiments, the heater 240 is configured to maintain a temperature of the shield 230 in a range of from 25° C. to 600° C.

In one or more embodiments, the processing chamber 200 comprises an adapter 245. The adapter 245 is located on an outer periphery of the top portion 201 in contact with and optionally supporting the target backing plate 205 and/or the target bond 206. In some embodiments, the adapter 245 extends to the heater 240. In some embodiments, the adapter 245 comprises a plenum 246 fluidly connected to the process cavity 203 via a space 252 between the top portion 201 and the shield 230. The adapter 245 can comprise any suitable material. In some embodiments, the adapter 245 comprises aluminium.

In one or more embodiments, the processing chamber 200 comprises a roughing line 247 connected to a switch valve manifold 248. In some embodiments, the plenum 246 is operatively connected to the roughing line 247 having the switch valve manifold 248. The switch valve manifold 248 is connected to a roughing pump 262. The switch valve manifold 248 is configured to allow a flow of gas from the process cavity 203 to the roughing pump 262 through the top gas flow path 233 and the space 252 when the switch valve manifold 248 is opened and to prevent flow to the roughing pump 262 when the switch valve manifold 248 is closed. In some embodiments, the processing chamber 200 is configured to allow a flow of gas into the process cavity 203 through the top gas flow path 233 when the switch valve manifold 248 is closed. In some embodiments, the switch valve manifold 248 is opened when in cleaning mode, for example.

In one or more embodiments, the processing chamber 200 comprises an abatement assembly 263 connected to the roughing pump 262. In cleaning mode, for example, the roughing pump 262 removes gas from the process cavity 203 via the top gas flow path 233 towards the abatement assembly 263. In one or more embodiments, the processing chamber 200 comprises an exhaust assembly 264 connected to the abatement assembly 263. In some embodiments, the exhaust assembly 264 comprises house exhaust. In cleaning mode, for example, the exhaust assembly 264 removes the gas from the abatement assembly 263 and the processing chamber 200.

The processing chamber 200 comprises a chamber body 250 forming an interior volume 251 of the processing chamber 200. A top of the interior volume 251 is closed by the top portion 201, the bottom portion 202, and the process cavity 203. In some embodiments, the chamber body 250 supports the adapter 245 from below. The interior volume 251 contains the substrate support 210, the grounding bracket 225, the shield 230, and the adapter 245 within the chamber body 250. The bottom gas flow path 239 fluidly connects the process cavity 203 to the interior volume 251 via a space between the shield 230 and the deposition ring 100. The chamber body 250 can comprise any suitable material. In some embodiments, the chamber body 250 comprises stainless steel.

In one or more embodiments, the processing chamber 200 comprises a containment o-ring 255 between the shield bottom end 232 and the adapter 245. The containment o-ring 255 is configured to prevent any fluid contact between the top gas flow path 233 and the interior volume 251 and/or the heater 240 via a space between the shield 230 and the adapter 245. In some embodiments, the containment o-ring 255 is resistant to fluoride radicals and/or fluorine sputtering.

In one or more embodiments, the bottom portion 202 comprises a shaft 253 and a hoop lift component 254. The substrate support 210 and the grounding bracket 225 are positioned on the shaft 253. The shaft 253 is operatively connected with the hoop lift component 254. In some embodiments, the hoop lift component 254 moves the bottom portion 202 up or down.

In one or more embodiments, the processing chamber 200 comprises an inert gas inlet 257. The inert gas inlet 257 functions to maintain a positive pressure in the interior volume 251. The positive pressure in the interior volume 251 prevents leaking of any gas into the interior volume 251 from the process cavity 203 or the space between the shield 230 and the adapter 245. In some embodiments, the inert gas comprises argon (Ar), helium (He), nitrogen (N₂), xenon (Xe), or combinations thereof. In some embodiments, the inert gas further comprises a protective gas. In some embodiments, the protective gas comprises oxygen (O₂) or hydrogen (H₂).

In one or more embodiments, the processing chamber 200 comprises a turbo pump housing 268 in fluid communication with the process cavity 203 through the bottom gas flow path 239.

In one or more embodiments, the processing chamber 200 comprises a process gas inlet 258. The process gas inlet 258 comprises a process gas inlet valve 249. In some embodiments, a process gas reservoir (not shown) is connected to the process gas inlet valve 249. When in deposition mode, the processing chamber 200 is configured to allow a flow of the process gas through the top gas flow path 233, the process cavity 203, and the bottom gas flow path 239. In some embodiments, the process gas inlet 258 can be used to deliver the process gas to the process cavity 203 via the top gas flow path 233.

In one or more unillustrated embodiments, the processing chamber 200 comprises a reactant inlet, and the reactant inlet comprises a reactant inlet path and a reactant inlet valve. In one or more embodiments, the reactant inlet valve is in fluid communication with the process cavity 203 through the top flow path 133.

In one or more embodiments, the reactant inlet path passes through the adapter 245 and opens into the process cavity 203 through a hole between the shield top end 231 and the shield bottom end 232. In some embodiments, the processing chamber 200 comprises more than one reactant inlet. In some embodiments, the processing chamber 200 comprises at least two reactant inlets. In some embodiments, the processing chamber 200 comprises two reactant inlets, the reaction inlets are 90° apart. In some embodiments, the reactant inlet comprises stainless steel.

In one or more unillustrated embodiments, the reactant inlet is connected to a reaction gas reservoir. In some embodiments, the reactant inlet path is connected to the reaction gas reservoir via the reactant inlet valve. In some embodiments, when in cleaning mode, the reactant inlet valve is opened establishing fluid communication between the process cavity 203 and the reaction gas reservoir. In some embodiments, when in deposition mode, the reaction inlet valve is closed disconnecting fluid communication between the process cavity 203 and the reaction gas reservoir.

In one or more embodiments, the reactant inlet is connected to a remote plasma source. In some embodiments, the reactant inlet path is connected to the remote plasma source via the reactant inlet valve. In some embodiments, when in cleaning mode, the reactant inlet valve is opened establishing fluid communication between the process cavity 203 and the remote plasma source. In some embodiments, when in deposition mode, the reaction inlet valve is closed disconnecting fluid communication between the process cavity 203 and the remote plasma source.

, in some embodiments, the bottom portion 202 comprises a sealing bracket 220. The sealing bracket 220 is positioned on an opposite side of the substrate support 210 from the target backing plate 205 so that the deposition ring 100 is between the target backing plate 205 and the sealing bracket 220. In some embodiments, the sealing bracket 220 comprises nickel plated stainless steel. In some embodiments, the grounding bracket 225 is located below the sealing bracket 220. In some embodiments, the sealing bracket 220 is secured to the grounding bracket 225 via a fastener 226. In some embodiments, the fastener 226 comprises stainless steel.

In some embodiments, the processing chamber 200 comprises a bellows assembly 238 connected to or in contact with the shield 230. In some embodiments, the bellows assembly 238 is located on an outer periphery of the shield 230 and below the shield bottom end 232. The bellows assembly 238 comprises a top bellows flange 235, a bellows 236, and a bottom bellows flange 237. The top bellows flange 235 is located below the shield bottom end 232 next to the contoured surface on the outer side of the shield bottom end 232. The top bellows flange 235 and the bottom bellows flange 237 support the bellows 236 therebetween. In some embodiments, one or more of the top bellows flange 235 and the bottom bellows flange 237 comprises nickel plated stainless steel.

In one or more embodiments, the processing chamber 200 comprises an elastomeric sealant between the top bellows flange 235 and the shield bottom end 232. In some embodiments, the elastomeric sealant prevents reactant leakage in the interior volume 251 through a space between the top bellows flange 235 and the shield bottom end 232. In some embodiments, the elastomeric sealant is resistant to fluoride radical and/or fluorine sputtering.

In some embodiments, the bottom gas flow path 239 further comprises a gap 241 between the sealing bracket 220 and the bellows assembly 238. Accordingly, in some embodiments, the bottom gas flow path 239 fluidly connects the process cavity 203 to the interior volume 251 via a space between the shield 230 and the deposition ring 100 and a space between the sealing bracket 220 and the bellows assembly 238.

In one or more embodiments, the process cavity 203 is fluidly connected to the interior volume 251 via the bottom gas flow path 239. In some embodiments, the deposition ring 100 and sealing bracket 220 are movable between a process position where there is a gap 241 between the sealing bracket 220 and the deposition ring 100. In one or more embodiments, the sealing bracket 220 contacts the bellows assembly 238. In some embodiments, the hoop lift component 254 moves the bottom portion 202 up to contact the sealing bracket 220 with the bottom bellows flange 237 and thereby sealing the process cavity 203. The hoop lift component 254 moves the bottom portion 202 down to contact the sealing bracket 220 with the bottom bellows flange 237 and thereby opening the bottom gas flow path 239.

In some embodiments, the turbo pump housing 268 is in fluid communication with the process cavity 203 through the bottom gas flow path 239 when the sealing bracket 220 and deposition ring 100 are in the process position. In some embodiments, the turbo pump housing 268 is isolated from the process cavity 203 via the bottom gas flow path 239 when the sealing bracket 220 and deposition ring 100 are in the cleaning position.

In some embodiments, one or more of the components of the processing chamber 200 are resistant to fluoride radicals and/or fluorine sputtering.

In some embodiments, one or more of the components of the processing chamber 200 are made of one or more of aluminum, aluminum oxide, yttria and/or nickel-plated SSL.

In one or more embodiments, the deposition ring 100 is configured to prevent unwanted deposition in the chamber body 250. For example, in one or more embodiments, the deposition ring 100 is configured to prevent deposition on a number of components in the chamber body 250, such as, for example, the substrate support 210 and/or the heater 240.

Additional embodiments of the disclosure are directed to a processing method comprising: exposing a semiconductor substrate in a physical vapor deposition (PVD) processing chamber to a target comprising a titanium-containing material to deposit a titanium nitride (TiN) film directly on the semiconductor substrate. The physical vapor deposition (PVD) processing chamber used to perform the processing method comprises the deposition ring described herein.

In one or more embodiments, the target sputters the titanium-containing material to the semiconductor substrate to deposit the titanium nitride (TiN) film directly on the semiconductor substrate. The titanium nitride (TiN) film can be deposited to any suitable thickness, and the thickness may vary depending on the application for which the titanium nitride (TiN) film is used.

In one or more embodiments, the semiconductor substrate is spaced a distance in a range of from 184 mm to 188 mm from the target.

One or more embodiments of the disclosure are directed to a non-transitory computer readable medium including instructions, that, when executed by a controller of a processing system (e.g., a processing system comprising a physical vapor deposition (PVD) processing chamber that includes the deposition ring described herein, cause the processing system to perform the processing method according to one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A deposition ring comprising:
a ring-shaped body having an upper portion and a lower portion, each of the upper portion and the lower portion independently comprising an inner diameter surface and an outer diameter surface defining an upper portion thickness and a lower portion thickness, and a top surface and a bottom surface defining an upper portion height and a lower portion height, the upper portion height greater than the lower portion height; and
a plurality of circumferentially spaced notches formed along an edge of the inner diameter surface of the lower portion, wherein at least a portion of the upper portion defines a convex shape.

2. The deposition ring of claim 1, wherein the ring-shaped body has an inner diameter in a range of from 10 inches to 12 inches.

3. The deposition ring of claim 1, wherein the ring-shaped body has an outer diameter in a range of from 13 inches to 15 inches.

4. The deposition ring of claim 1, wherein a sum of the upper portion height and the lower portion height is in a range of from 0.2 inches to 0.3 inches.

5. The deposition ring of claim 1, wherein the deposition ring consists essentially of aluminum oxide (Al₂O₃).

6. The deposition ring of claim 1, wherein each of the plurality of the circumferentially spaced notches is tapered inwardly.

7. The deposition ring of claim 1, wherein the plurality of circumferentially spaced notches includes three notches.

8. A processing chamber comprising:
a target backing plate in a top portion of the processing chamber;
a substrate support in a bottom portion of the processing chamber, the substrate support having a support surface spaced a distance from the target backing plate to form a process cavity;
a deposition ring positioned at an outer periphery of the substrate support; and
a shield forming an outer bound of the process cavity, wherein the shield has a top shield end in the top portion of the processing chamber and a bottom shield end in the bottom portion of the processing chamber, the top end positioned around a periphery of the target backing plate and the bottom end positioned around a periphery of the substrate support, the bottom end including a contoured surface having a complementary shape to the outer portion of the deposition ring.

9. The processing chamber of claim 8, wherein the processing chamber is a physical vapor deposition (PVD) chamber configured to deposit a titanium nitride (TiN) film directly on a semiconductor substrate positioned on the substrate support.

10. The processing chamber of claim 8, wherein the top portion of the processing chamber comprises a top gas flow path between a periphery of the target backing plate and the top of the shield.

11. The processing chamber of claim 8, wherein the bottom portion of the processing chamber comprises a bottom gas flow path between the shield and the deposition ring.

12. The processing chamber of claim 8, wherein the deposition ring comprises a ring-shaped body having an upper portion and a lower portion, each of the upper portion and the lower portion independently comprising an inner diameter surface and an outer diameter surface defining an upper portion thickness and a lower portion thickness, and a top surface and a bottom surface defining an upper portion height and a lower portion height, the upper portion height greater than the lower portion height, and at least a portion of the upper portion defines a convex shape.

13. The processing chamber of claim 12, wherein the deposition ring comprises a plurality of circumferentially spaced notches formed along an edge of the inner diameter surface of the lower portion.

14. The processing chamber of claim 12, wherein the ring-shaped body has an inner diameter in a range of from 10 inches to 12 inches.

15. The processing chamber of claim 12, wherein the ring-shaped body has an outer diameter in a range of from 13 inches to 15 inches.

16. The processing chamber of claim 12, wherein a sum of the upper portion height and the lower portion height is in a range of from 0.2 inches to 0.3 inches.

17. The processing chamber of claim 12, wherein the deposition ring consists essentially of aluminum oxide (Al₂O₃).

18. A processing method comprising:
exposing a semiconductor substrate in a physical vapor deposition (PVD) processing chamber to a target comprising a titanium-containing material to deposit a titanium nitride (TiN) film directly on the semiconductor substrate, the physical vapor deposition (PVD) processing chamber comprising the deposition ring of claim 1.

19. The processing method of claim 18, wherein the target sputters the titanium-containing material to the semiconductor substrate to deposit the titanium nitride (TiN) film.

20. The processing method of claim 18, wherein the semiconductor substrate is spaced a distance in a range of from 184 mm to 188 mm from the target.
